(19) United States
(12) Patent Application Publication
(10) Pub. No.: US 2020/0043876 A1
(43) Pub. Date: Feb. 6, 2020

(54) Adhesion Enhancing Structures for a Package

(71) Applicant: Infineon Technologies AG, Neubiberg (DE)

(72) Inventors: Evelyn Napetschnig, Diex (AT); Wei Cheat Lee, Penang (MY); Wei Lee Lim, Permatang Pauh (MY); Frank Renner, Regensburg (DE); Michael Rogalli, Rottenburg (DE)

(21) Appl. No.: 16/520,597

(22) Filed: Jul. 24, 2019

(30) Foreign Application Priority Data
Jul. 31, 2018 (DE) 102018118544.8

(51) Int. Cl. H01L 23/00

(52) U.S. Cl. CPC H01L 24/05; H01L 24/03; H01L 2224/02165; H01L 2224/03011; H01L 2224/05647; H01L 2224/056; H01L 2224/0218; H01L 2224/05624

(57) ABSTRACT

A package includes an electronic chip having a pad. The pad is at least partially covered with adhesion enhancing structures. The pad and the adhesion enhancing structures have at least aluminium in common.

### TECHNICAL FIELD

The present invention relates to packages and a method.

### BACKGROUND

A package, for instance for automotive applications, provides a physical containment for one or more electronic chips comprising one or more integrated circuit elements. Examples of integrated circuit elements of packages are a field effect transistor, an insulated-gate bipolar transistor (IGBT), a diode, and passive components (such as an inductance, a capacity, a resistor). Moreover, such packages may be used for producing a system-in-package.

For manufacturing a package, at least one electronic chip may be encapsulated by an appropriate encapsulant or another dielectric structure of the package.

However, there is still potentially room to improve reliability of a package, in particular in terms of the mechanical integrity of the package.

### SUMMARY

There may be a need for a chip package which is mechanically robust.

According to an exemplary embodiment, a robust package is provided which comprises an electronic chip having a pad, wherein the pad is at least partially covered with adhesion enhancing structures, and wherein the pad and the adhesion enhancing structures have at least one chemical element (preferably, but not necessarily aluminium) in common.

According to another exemplary embodiment, a package is provided which comprises a chip carrier, an electronic chip mounted on the chip carrier, and a dielectric structure covering at least part of a surface of at least one of the chip carrier and the electronic chip, wherein at least part of the covered surface comprises hydrothermally formed adhesion enhancing structures.

According to still another exemplary embodiment, a method of forming a semiconductor package is provided, wherein the method comprises providing an aluminium based surface, and roughening the surface with adhesion enhancing structures formed by a hydrothermal process.

According to an exemplary embodiment, a surface (for instance comprising aluminium) may be treated by a hydrothermal process for triggering formation of adhesion enhancing structures. The latter may be capable of enhancing adhesion between the covered surface and a dielectric structure formed thereon. As a result, a package may be manufactured which has highly advantageous properties in terms of mechanical integrity and electrical performance. The proper mechanical integrity results from the strongly suppressed tendency of the delamination between surface and dielectric structure thanks to the provision of the hydrothermally produced adhesion enhancing structures. The advantageous electrical integrity results from the fact that a proper connection between the surface and the dielectric structure may be ensured which prevents undesired phenomena such as moisture entering tiny gaps between improperly connected dielectric structure and electrically conductive surfaces in the package. Advantageously, the mentioned (preferably aluminium comprising) adhesion enhancing structures on the (preferably aluminium comprising) surface may be manufactured hydrothermally, i.e. by the combination of an aqueous medium and heat, i.e. in a simple way and without involving hazardous substances. It may be in particular advantageous that no chromium is required for such a hydrothermal process.

Thus, an exemplary embodiment uses adhesion enhancing structures grown via temperature hydrolysis on aluminium based metal areas or Al₂O₃ layer covered copper areas as adhesion promoter for robust packaging. These adhesion enhancing structures can be easily monitored by optical inspection. The implementation may keep the effort for the adhesion promoting process reasonably small. The adhesion enhancing structures can be used advantageously as adhesion promoter between the pad or other surfaces on the one hand and a dielectric structure such as an encapsulant on the other hand. Furthermore, hydrothermally formed adhesion enhancing structures may contribute to reduce or even eliminate unhealthy and hazardous material.

A gist of an exemplary embodiment is the formation of a semiconductor package having an improved adhesion between an aluminium contact pad and a dielectric structure (such as a mold component) of the semiconductor package. At a surface of the aluminium contact pad, a dendrite structure or other kind of adhesion enhancing structures may be arranged to provide a rough surface. Further, the adhesion enhancing structures may be grown in a hydrothermal process. In particular, the grown adhesion enhancing structures may enable low cost and high-quality mold compound adhesion on aluminium pads or other surfaces covered with the adhesion enhancing structures.

According to an exemplary embodiment, a method for forming a semiconductor package is provided which may provide an improved adhesion between an aluminium contact pad and a dielectric structure such as a mold component of the semiconductor package. At a surface of the aluminium, contact-pad, dendrite structures or other kind of adhesion enhancing structures may be arranged to provide a roughened surface. Advantageously, the adhesion enhancing structures may be grown in a hydrothermal process.

In the following, further exemplary embodiments of the packages and the method will be explained.

In the context of the present application, the term “package” may particularly denote at least one partially or fully encapsulated and/or coated electronic chip with at least one, direct or indirect, external electric contact.

In the context of the present application, the term “electronic chip” may particularly denote a chip (more particularly a semiconductor chip) providing an electronic function. The electronic chip may be an active electronic component. In one embodiment, the electronic chip is configured as a controller chip, a processor chip, a memory chip, a sensor chip or a micro-electromechanical system (MEMS). In an alternative embodiment, it is also possible that the electronic chip is configured as a power semiconductor chip. Thus, the electronic chip (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide, gallium nitride or gallium nitride on silicon). A semiconductor power chip may comprise one or more field effect transistors, diodes, inverter circuits, half-bridges, full-bridges, drivers, logic circuits, further devices, etc. The electronic chip may be a naked die or may be already packaged or encapsulated. However, the electronic chip may also be a passive component such a capacitor or a resistor.

In the context of the present application, the term “chip carrier” may particularly denote an at least partially electrically conductive structure which serves simultaneously as a mounting base for one or more electronic chips and also contributes to the electric connection of the electronic chip(s) with an electronic environment of the package. In other words, the chip carrier may fulfil a mechanical support function and an electric connection function. A preferred embodiment of a carrier is a leadframe.

In the context of the present application, the term “adhesion enhancing structures” or adhesion promoting structures may particularly denote physical bodies extending from a surface (such as a pad), preferably in a randomly oriented and/or in an intermingling way, to increase roughness compared to the roughness of the surface without adhesion enhancing structures. The adhesion enhancing structures may be adhesion enhancing fibers which may be randomly oriented and may form a fiber network. In particular, the adhesion enhancing structures may share at least one material (preferably aluminium) with the surface from which they extend and/or with which they are integrally formed. For example, the adhesion enhancing structures may be fibers, filaments, hairs, or strands. Descriptively speaking, the adhesion enhancing structures may be embodied as or may be denoted as dendrites.

In the context of the present application, the term “hydrothermal process” may particularly denote a process combining the presence of water (in particular only or substantially only water) and thermal energy (in particular thermal energy provided by heating the water to a temperature above room temperature and below evaporation temperature) for treating the material of a surface (in particular an aluminium surface such as an aluminium pad). Preferably, the hydrothermal process may result in the formation of the adhesion enhancing structures based on material of the underlying surface.

In the context of the present application, the term “dielectric structure” may particularly denote an electrically insulating material covering the surface and being in (preferably direct) contact with at least part of the adhesion enhancing structures. For instance, such a dielectric structure may be an encapsulant such as a mold compound.

In an embodiment, the adhesion enhancing structures comprise or consist of adhesion enhancing fibers, in particular at least one of nanofibers and microfibers. Fibers may denote long strands of material. The adhesion enhancing fibers may be randomly oriented and may be intermingled so as to form a layer with a rough exterior surface. Nanofibers may be fibers having a dimension in the range of nanometers. Microfibers may be fibers having a dimension in the range of micrometers.

In an embodiment, the package comprises a dielectric structure at least partly directly covering the electronic chip. More specifically, the dielectric structure may at least partly directly cover one or more pads of the electronic chip. Preferably, the dielectric structure may at least partly directly cover the adhesion enhancing structures on the pad. Additionally or alternatively, such a dielectric structure may also cover at least part of a chip carrier on which the at least one electronic chip may be mounted and/or may cover at least part of a connection element connecting the electronic chip with the chip carrier.

In an embodiment, the dielectric structure comprises or consists of an encapsulant at least partially encapsulating at least the electronic chip. In the context of the present application, the term “encapsulant” may particularly denote a substantially electrically insulating and preferably thermally conductive material surrounding an electronic chip and/or part of a chip carrier and/or part of a connection element to provide mechanical protection, electrical insulation, and optionally a contribution to heat removal during operation. Such an encapsulant can be, for example, a mold compound. Filler particles (for instance SiO₂, Al₂O₃, Si₃N₄, BN, AlN, diamond, etc.), for instance for improving thermal conductivity, may be embedded in a plastic-based (for instance epoxy-based) matrix of the encapsulant.

Forming the dielectric structure may comprise at least one the group consisting of molding (in particular injection molding), coating, and casting. Molding may be denoted as a process of manufacturing by shaping liquid or pliable raw material using a rigid frame which may be denoted as mold. A mold may be a hollowed-out block or set of tools with an interior hollow volume filled with a liquid or pliable material. The liquid hardens inside the mold, adopting its shape.

In an embodiment, the adhesion enhancing structures comprise aluminium oxide and/or aluminium hydroxide. Aluminium oxide may be denoted as a chemical compound of aluminium and oxygen (in particular with the chemical formula Al₂O₃). Aluminium hydroxide may be formed in the presence of aluminium and water (and may in particular have the chemical formula Al(OH)₃). Aluminium oxide and/or aluminium hydroxide may be formed during a hydrothermal processing of aluminium material of a surface in contact with hot water.

In an embodiment, the pad comprises or consists of aluminium. In particular the pad may comprise at least one of pure aluminium, aluminium-copper, aluminium-silicon-copper, and copper with an aluminium oxide coating. When the bulk or base material of the pad comprises aluminium (and optionally one or more further materials such as copper, silicon, etc.), the treatment of this pad material with hot water in a hydrothermal process may result in the formation of adhesion enhancing structures. However, it has also turned out to be possible to treat a pad comprising for instance copper as bulk or base material and being covered with a thin surface layer of aluminium oxide (for instance having a thickness in the range between 1 nm and 20 nm, for instance 6 nm) hydrothermally to thereby produce adhesion enhancing structures. In the latter embodiment, aluminium material of the surface layer may be converted into and/or may react to form adhesion enhancing fibers. Within investigations, it turned out to be possible to successfully grow dendrites on aluminium based pads, as well as on copper pads with an atomic layer deposited (ALD, Atomic Layer Deposition) Al₂O₃ layer on top.

In an embodiment, the adhesion enhancing structures form a substantially homogeneous layer. Such a substantially homogeneous layer may have a substantially constant thickness and/or may have a substantially homogeneous density over the entire surface being covered with the adhesion enhancing structures. This ensures that the promoted adhesion effect is effective over a large area with substantially constant intensity. Weak spots in terms of adhesion between dielectric material and the surface may therefore be prevented.

In an embodiment, the adhesion enhancing structures have a height in a range between 50 nm and 1000 nm, in particular between 100 nm and 300 nm. Main design parameter for adjusting the thickness is the treatment time for which the surface is treated hydrothermally, in particular is immersed in hot water.

In an embodiment, the package comprises a chip carrier on which the electronic chip is mounted. For instance, such a chip carrier may comprise a leadframe and/or a ceramic sheet covered on both opposing main surfaces with a respective metallic layer (in particular a Direct Aluminium Bonding (DAB) substrate and/or a Direct Copper Bonding (DCB) substrate).

In an embodiment, the carrier is a leadframe. Such a leadframe may be a sheet-like metallic structure which can be patterned so as to form one or more mounting sections for mounting the one or more electronic chips of the package, and one or more lead sections for electric connection of the package to an electronic environment when the electronic chip(s) is/are mounted on the leadframe. In an embodiment, the leadframe may be a metal plate (in particular made of copper) which may be patterned, for instance by stamping or etching. Forming the chip carrier as a leadframe is a cost-efficient and mechanically as well as electrically highly advantageous configuration in which a low ohmic connection of the at least one electronic chip can be combined with a robust support capability of the leadframe. Furthermore, a leadframe may contribute to the thermal conductivity of the package and may remove heat generated during operation of the electronic chip(s) as a result of the high thermal conductivity of the metallic (in particular copper) material of the leadframe. A leadframe may comprise for instance aluminum and/or copper.

In an embodiment, the method comprises forming the adhesion enhancing structures on an electrically conductive surface. In particular, the (preferably aluminium comprising) surface on which adhesion enhancing fibers may be grown hydro thermally may be a metallic surface (for instance comprising metallic aluminium material). However, it is also possible that the adhesion promoting effect is formed by hydrothermally growing adhesion promoting fibers on a dielectric or electrically insulating surface (for instance comprising dielectric aluminium oxide material). As a result, it is also possible to improve adhesion at a dielectric (preferably aluminium comprising) surface to be encapsulated by a mold compound in the package.

In a preferred embodiment, the method comprises converting material of the surface into at least part of the adhesion enhancing structures. For instance, the adhesion enhancing structures may consequently be integrally formed with the surface from which they grow and extend. In other words, the hydrothermal process may comprise the procedure of hydrothermally converting or modifying material of the surface into the adhesion enhancing structures. Hence, the adhesion enhancing structures (in particular adhesion enhancing fibers) may be created from surface material (in particular from pad material, chip carrier material and/or connection element material). In particular, by hydrothermally processing the surface, material of the surface itself may be modified chemically so as to form the adhesion enhancing structures. As a result, a proper integrity between remaining material of the surface on the one hand and the integrally formed adhesion enhancing structures on the other hand may be obtained. As a result of this material conversion, the material of the surface on the one hand and the material of the adhesion enhancing structures may share at least one chemical element or may be even chemically identical.

In an embodiment, the method comprises providing an electronic chip with a pad providing the (in particular electrically conductive) surface. Such a pad may provide an electric contact between a semiconductor die on the one hand and an electrically conductive connection element (such as a bond wire, a bond ribbon or a clip) encapsulated in the package on the other hand. A clip may be a three-dimensionally bent plate type connection element which has two planar sections to be connected to an upper main surface of the respective electronic chip and an upper main surface of the chip carrier, wherein the two mentioned planar sections are interconnected by a slanted connection section. As an alternative to such a clip, it is possible to use a bond wire or bond ribbon which is a flexible electrically conductive wire or ribbon shaped body having one end portion connected to the upper main surface of the respective chip and having an opposing other end portion being electrically connected to the chip carrier. Within the encapsulant, an electrically conductive connection may be formed by the connection element between a chip pad at an upper main surface of the chip mounted on a mounting section of the carrier on the one hand and a lead section of the carrier on the other hand.

In an embodiment, the package comprises the connection element electrically coupling the electronic chip with the chip carrier and having a surface being at least partially covered by the dielectric structure. The covered surface of the connection element may comprise hydrothermally formed adhesion enhancing structures. Thus, the adhesion promotion may also be provided on a connection element such as a bond wire, bond ribbon or clip which can also be encapsulated by an encapsulant such as a mold compound. This further improves the mechanical integrity of the package.

In an embodiment, the method comprises providing the (in particular electrically conductive) surface based on aluminium. By a hydrothermal process, such aluminium material may then be used for the formation of the adhesion enhancing structures. As a result, the adhesion enhancing structures then comprise or consist of aluminium material as well.

In the following, some specific embodiments relating to the hydrothermal process will be described:

In an embodiment, the method comprises forming the adhesion enhancing structures by placing the electrically conductive surface in a hot (i.e. heated above ambient temperature) aqueous solution. Such an aqueous solution may comprise or consist of water.

In an embodiment, the method comprises heating the aqueous solution to a temperature in a range between 50° C. and 90° C., in particular in a range between 70° C. and 80° C. The temperature of the hot or heated water should be high enough to ensure an efficient production of adhesion enhancing structures based on material of the underlying surface (in particular of an underlying pad). On the other hand, the temperature of the aqueous solution should be sufficiently low to prevent evaporation of the aqueous solution. Good results can be achieved over the entire temperature range from 50° C. to 90° C. Extraordinary results can be obtained within the temperature range between 70° C. and 80° C.

In an embodiment, the method comprises providing distilled or purified water as the aqueous solution. Distilled water may denote water that has been boiled into steam and condensed back into liquid in a separate container. Impurities in the original water that do not boil below or at the boiling point of water remain in the original container. Thus, distilled water is one type of purified water which may be advantageously used for exemplary embodiments, wherein other types of purified water may be used for the aqueous solution as well. Pure water may thus serve as a highly biocompatible as well as highly efficient medium for triggering a hydrothermal formation of adhesion enhancing structures (in particular adhesion enhancing fibers or dendrites).

In an embodiment, the method comprises maintaining the electrically conductive surface (in particular an entire electronic chip) in the heated aqueous solution for a time interval between 1 minute and 10 hours, in particular for a time interval between 10 minutes and 3 hours. The duration may be used as a design parameter for defining the thickness of the layer of adhesion enhancing structures. For instance, keeping aluminium pads in 75° C. hot water for 10 minutes may result in the formation of adhesion enhancing structures of a thickness of about 500 nm.

In an embodiment, the method comprises at least partially encapsulating the surface with the adhesion enhancing structures thereon, in particular by molding. After having roughened the surface (in particular pad) by the formation of the adhesion enhancing structures, the latter may be directly covered with the encapsulant. The encapsulant material thus properly adheres to the adhesion enhancing structures, thereby ensuring a high mechanical integrity of the entire formed package.

In an embodiment, the at least one electronic chip comprises a semiconductor chip, in particular a power semiconductor chip. In particular when the at least one electronic chip is a power semiconductor chip, significant amount of heat generated during operation of the package may result in thermal load acting on the electric and mechanical interfaces of the package. However, due to the adhesion enhancing structures as disclosed herein, damage of the package may be prevented even under such harsh conditions.

In an embodiment, the electronic chip contains at least one, in particular at least three or at least eight-transistors (such as field-effect transistors, in particular metal oxide semiconductor field-effect transistors). Typically, the electronic chip may comprise many transistors.

As substrate or wafer forming the basis of the electronic chip(s), a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE FIGURES

The accompanying drawings, which are included to provide a further understanding of exemplary embodiments and constitute a part of the specification, illustrate exemplary embodiments.

In the drawings:

FIG. 1 shows a surface morphology of an aluminium-based pad before carrying out a hydrothermal process according to an exemplary embodiment.

FIG. 2 shows a surface morphology of the aluminium-based pad of FIG. 1 after having carried out the hydrothermal process according to an exemplary embodiment.

FIG. 3 shows a side view of adhesion enhancing structures on an aluminium pad manufactured according to an exemplary embodiment after a hydrothermal process.

FIG. 4 shows a top view of adhesion enhancing structures on an aluminium pad manufactured according to an exemplary embodiment after a hydrothermal process.

FIG. 5 shows an aluminium-based surface with adhesion enhancing structures according to an exemplary embodiment before attaching a tape in terms of an adhesion test.

FIG. 6 shows the aluminium-based surface with adhesion enhancing structures of FIG. 5 with attached tape in terms of the adhesion test.

FIG. 7 shows the aluminium-based surface with adhesion enhancing structures of FIG. 6 after removing the type in terms of the adhesion test.

FIG. 8 shows a cross-sectional view of a package according to an exemplary embodiment.

FIG. 9 to FIG. 13 show top views of an aluminium pad surface after exposure times of 10 (FIG. 9), 20 (FIG. 10), 30 (FIG. 11), 60 (FIG. 12) and 180 minutes (FIG. 13), respective1y.

FIG. 14 to FIG. 18 show side views of the pad surface of FIG. 9 to FIG. 13 after exposure times of 10 (FIG. 14), 20 (FIG. 15), 30 (FIG. 16), 60 (FIG. 17) and 180 (FIG. 18) minutes, respectively.

FIG. 19 shows a top view and FIG. 20 shows a side view of a pad surface after exposure of 20 minutes of an Al₂O₃ layer covered copper pad using an ALD (Atomic Layer Deposition) deposition process.

FIG. 21 shows a top view and FIG. 22 shows a side view of Al—O—H dendrites on copper pads covered with an Al₂O₃ layer formed by ALD after 10 minutes of spray-on of 70° C. hot deionized water.

FIG. 23 illustrates a cross-sectional view of a package according to an exemplary embodiment.

FIG. 24 illustrates a cross-sectional view of a package according to another exemplary embodiment.

FIG. 25 is a flowchart illustrating a method of forming a semiconductor package according to an exemplary embodiment.

### DETAILED DESCRIPTION

The illustrations in the drawings is schematic. Before describing further exemplary embodiments in further detail, some basic considerations of the present invention will be summarized based on which exemplary embodiments have been developed.

According to an exemplary embodiment, adhesion enhancing structures (in particular aluminium oxide dendrites) may be grown on a (in particular aluminium comprising) surface such as a pad to enable good mold compound adhesion on this surface.

In terms of semiconductor packages, a high reliability is required. One of the major issues is the mold compound adhesion in the package especially for the adhesion between metal pad areas and mold compound. At this interface, it is advantageous to render a surface as rough as possible to enable, descriptively speaking, an interdiffusion area between mold compound resin and the surface.

According to an exemplary embodiment, a reliable protection against undesired delamination of the package can be accomplished by a very simple process with simple chemistry. It has turned out that a proper homogeneity of the growth of adhesion enhancing structures may render proper adhesion possible without facing quality issues. Apart from the simple processing, a process according to an exemplary embodiment has also advantages in terms of work security and health restrictions due to healthy and non-hazardous components. The simple process and the corresponding simple tools allow the manufacture with low effort because of cheap material and simple tools with small space consumption.

An exemplary embodiment manufactures aluminium hydroxide adhesion enhancing structures (in particular adhesion enhancing fibers) grown in a hydrothermal process providing a low effort and healthy solution. Results have shown a very good conformity and reproducibility of the dendrite growth. Within experiments, samples with aluminium based pads as well as pads with an ALD-manufactured Al₂O₃ layer covered copper pads have been investigated. The dendrites were grown by placing bare chips or assembled chips on leadframe into for instance 75° C. hot water for an appropriate time.

Exemplary embodiments allow the manufacture of robust packages with zero or extremely low tendency of delamination. At the same time, exemplary embodiments can be advantageously carried, out without adding further materials to the system and. avoiding complicated hazardous processes.

More generally, and also referring to FIG. 5 described, below in further detail, a manufacturing process of forming a semiconductor package 100 according to an exemplary embodiment may be as follows:

Firstly, an electronic chip 102 may be provided with one or more contact pads 104 comprising aluminium and having an exposed electrically conductive surface 112. For example, a respective contact pad 104 may be made of pure aluminium, aluminium-copper, or aluminium-silicon-copper. It is also possible that a respective contact pad 104 is composed of a copper base with a thin aluminium oxide coating. Aluminium oxide is electrically insulating, so that the surface 112 on which adhesion enhancing structures 106 will be grown later may be also electrically insulating rather than electrically conductive.

Thereafter, the method may comprise roughening a surface 112 of the one or more contact pads 104 using a hydrothermal process. In terms of this hydrothermal process, it is possible to grow adhesion enhancing structures 106 (in particular adhesion enhancing fibers or dendrite structures which may have dimensions in the order of magnitudes of nanometers to micrometers) on the pad 104 and on the basis of material of the pad 104. In other words, the pad 104 itself may be the source of material which forms the adhesion enhancing structures 106 integral with the pad 104. Therefore, the hydrothermal process hydrothermally converts material of the surface 112 into the adhesion enhancing structures 106 to thereby intrinsically grow rather than deposit the adhesion enhancing structures 106. As a consequence, the adhesion enhancing structures 106 formed based on the pad 104 (comprising aluminium) may comprise aluminium as well. Thus, the adhesion enhancing structures 106 and the pad 104 may both comprise aluminium, i.e. may have at least one chemical element (in particular Al) in common. Thus, the adhesion enhancing structures 106 may be formed by modifying or converting material of the surface 112 of the respective pad 104 into the adhesion enhancing structures 106.

In terms of the mentioned hydrothermal process for forming the adhesion enhancing structures 106, the electronic chip 102 with the one or more pads 104 having the electrically conductive surface 112 may be placed in a hot aqueous solution, more specifically may be immersed in heated water. Preferably, the aqueous solution may be heated to a temperature preferably between 7° C. and 80° C., for instance to 75° C. This temperature selection may ensure an efficient formation of the adhesion enhancing fibers. As the aqueous solution, deionized water or distilled water may be used. The electronic chip 102 with the at least one pad 104 having the electrically conductive surface 112 may be kept immersed in the heated aqueous solution for a selectable time interval of for instance between 10 minutes and 3 hours. The duration for which the electronic chip 102 remains immersed in the purified water determines the thickness of the layer of adhesion enhancing structures 106 being integrally formed on the surface 112 of the respective pad 104. After formation of the adhesion enhancing structures 112, the surface 112 has an increased roughness which improves the adhesion properties of a mold compound or another encapsulant to be formed subsequently.

Thus, the method comprises subsequently encapsulating the electronic chip 102 with the one or more pads 104 having the surface 112 covered with adhesion enhancing structures 106 by an encapsulant as dielectric structure 108 such as a mold compound by carrying out a molding procedure,

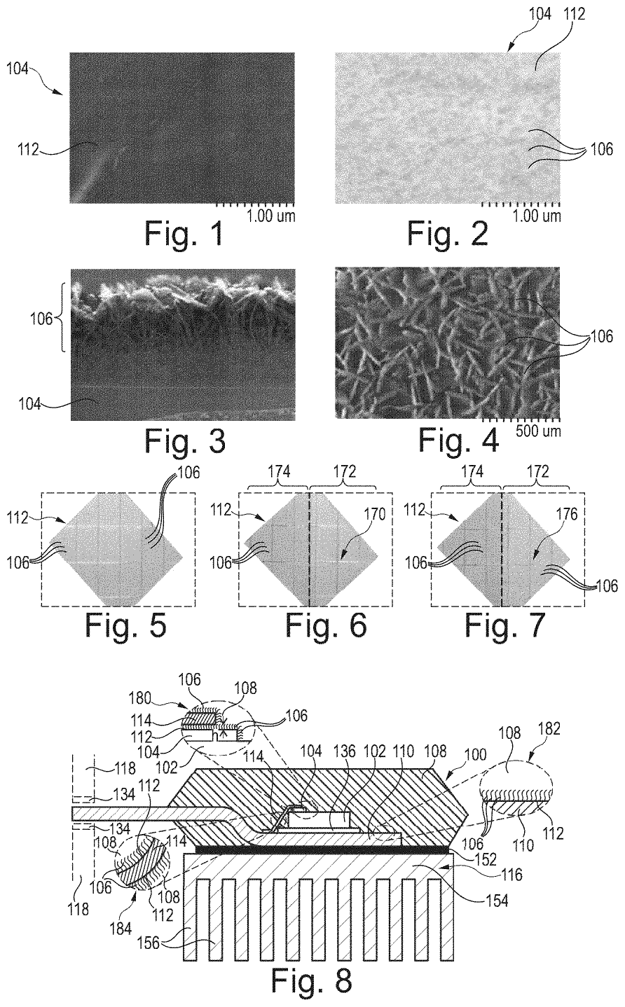

FIG. 1 shows a surface morphology of an aluminium-based pad 104 before an exposed surface 112 of the pad 104 is made subject of a hydrothermal process according to an exemplary embodiment. FIG. 2 shows a surface morphology of the aluminium-based pad 104 of FIG. 1 after the hydrothermal process according to an exemplary embodiment has formed adhesion enhancing structures 106 on the surface 112, i.e. after having formed the adhesion enhancing structures 106 in form of nanofibers. Thus, FIG. 1 and FIG. 2 illustrate the surface morphology of an aluminium based pad 104 before (FIG. 1) and after (FIG. 2) the above-described hydrothermal process. FIG. 1 and FIG. 2 show scanning electron microscope (SEM) images.

As can be taken from FIG. 2, a homogenous coverage of the surface 112 by the adhesion enhancing structures 106 has been found after the described treatment.

According to the exemplary embodiment of the method to which FIG. 1 and FIG. 2 refer, a Teflon (polytetrafluoroethylene) beaker was overflowed with deionized water (DI water) for 30 minutes. After that, the beaker was filled with 80 ml of deionized water at room, temperature. The beaker including its water was heated on a hotplate to 75° C., and a sample on which adhesion enhancing structures were to be formed was immersed in the water. After an appropriate exposure time, the beaker was removed from, the hotplate and was allowed to cool to room temperature. The sample was taken out of the beaker.

FIG. 3 shows a side view of adhesion enhancing structures 106 on an aluminium pad 104 manufactured according to an exemplary embodiment after a hydrothermal process. FIG. 4 shows a top view of the adhesion enhancing structures 106 on the aluminium pad 104 manufactured. according to this exemplary embodiment after the hydrothermal process. Thus, FIG. 3 and FIG. 4 show the adhesion enhancing structures 106 on experimentally captured images (SEM, TRIM, transmission electron microscope).

Analysis via SEM, TEM and EDX (energy dispersive X-ray spectroscopy) indicate that the adhesion enhancing structures 106 grow very homogenously, for instance with an approximate thickness of 200 nm. As can be taken in particular from FIG. 3, the adhesion enhancing structures 106 form a substantially homogeneous layer. It can also be seen experimentally that the interface between pad 104 and the adhesion enhancing structures 106 is very smooth without signs of inhomogeneous corrosion. It can also be confirmed experimentally that the composition is as well homogenous and that the adhesion enhancing structures 106 are aluminium-(hydro)-oxides.

FIG. 5 to FIG. 7 show results of an adhesion test of an aluminium-based surface 112 with adhesion enhancing structures 106 according to an exemplary embodiment.

FIG. 5 shows the aluminium-based surface 112 with adhesion enhancing structures 106 according to an exemplary embodiment before attaching a tape in terms of the adhesion test.

FIG. 6 shows the aluminium-based surface 112 with the adhesion enhancing structures 106 of FIG. 5 with attached tape 170 in a portion 172 only in terms of the adhesion test. Another portion 174 has not been covered by the tape 170.

FIG. 7 shows the aluminium-based surface 112 with the adhesion enhancing structures 106 of FIG. 6 after removing the tape 170 in terms of the adhesion test, i.e. after having removed tape 170 from portion 172. As can be taken from FIG. 7, glue residues 176 are visible which indicate proper adhesion properties.

The described adhesion test with sticky tape 170 shows that the adhesion enhancing structures 106 increase the adhesion while the adhesion enhancing structures 106 are not breaking easily, see FIG. 5 to FIG. 7.

FIG. 8 illustrates a cross-sectional view of a package 100 configured as an encapsulated electronic chip 102 on a chip carrier 110 according to an exemplary embodiment. The electronic chip 102 may have one or more pads 104. More specifically, FIG. 8 illustrates a cross-sectional view of the package 100, which is embodied as a Transistor Outline (TO) package, according to an exemplary embodiment. The package 100 is mounted on a mounting base 118, here embodied as printed circuit board (PCB).

The mounting base 118 comprises an electric contact 134 embodied as a plating in a through hole of the mounting base 118. When the package 100 is mounted on the mounting base 118, electronic chip 102 of the electronic component 100 is electrically connected to the electric contact 134 via electrically conductive chip carrier 110, here embodied as a leadframe, of the package 100.

The electronic chip 102 (which is here embodied as a power semiconductor chip) is mounted adhesively or soldered (by e.g. electrically conductive adhesive, solder paste, solder wire or diffusion soldering) on the chip carrier 110 (see reference numeral 136). An encapsulant (here embodied as mold compound) forms a dielectric structure 108 and encapsulates part of the leadframe-type chip carrier 110 and the electronic chip 102. As can be taken from FIG. 8, pad 104 on an upper main surface of the electronic chip 102 is electrically coupled to the partially encapsulated leadframe-type chip carrier 110 via a fully encapsulated clip-type or bond wire type connection element 114.

During operation of the power package 100, the power semiconductor chip in form of the electronic chip 102 generates heat. For ensuring electrical insulation of the electronic chip 102 and removing heat from an interior of the electronic chip 102 towards an environment, an electrically insulating and thermally conductive interface structure 152 is provided which covers an exposed surface portion of the leadframe-type chip carrier 110 and a connected surface portion of the encapsulant-type dielectric structure 108 at the bottom of the package 100. The thermally conductive property of the interface structure 152 promotes a removal of heat from the electronic chip 102, via the electrically conductive leadframe-type chip carrier 110, through the interface structure 152 and towards a heat dissipation body 116. The heat dissipation body 116, which may be made of a highly thermally conductive material such as copper or aluminium, has a base body 154 directly connected to the interface structure 152 and has a plurality of cooling fins 156 extending from the base body 154 and in parallel to one another so as to remove the heat towards the environment.

Conventionally, a package 100 of the type shown in FIG. 8 may suffer from delamination between mold material of the dielectric structure 108 on the one hand and material of the various components (in particular pad 104, chip carrier 110, connection element 114) of the package 100 encapsulated within and directly contacting dielectric structure 108 on the other hand. Highly advantageously, the package 100 reliably prevents any tendency of the delamination or poor adhesion within the dielectric structure 108 by providing hydrothermally formed adhesion enhancing structures 106 at an interface between the dielectric structure 108 on the one hand and one or more of the mentioned constituents on the other hand. This will be described in the following in further detail:

Firstly referring to detail 180, it is shown in FIG. 8 that the dielectric structure 108 covers an electrically conductive surface 112 of the pad 104 of the electronic chip 102. In order to improve the roughness and therefore the adhesion properties, the electrically conductive surface 112 is provided with adhesion enhancing structures 106 which are configured as intermingled nanofibers. For instance, the pad 104 may be made of aluminium and the adhesion enhancing structures 106 may comprise aluminium as well, for instance may comprise aluminium oxide or aluminium hydroxide as a result of a hydrothermal manufacturing process, as described above. As a result, the dielectric structure 108 directly covers exposed portions of the adhesion enhancing structures 106 on the pad 104 and therefore properly adheres to the pad 104 via its adhesion enhancing structures 106. The adhesion enhancing structures 106 may have a height, h, of for instance 500 nm.

Now referring to a further detail 182, the package 100 also comprises hydrothermally formed adhesion enhancing structures 106 comprising aluminium at an interface between the leadframe-type chip carrier 110 and the dielectric structure 108. In order to form the adhesion enhancing structures 106 in a corresponding manner as described above on the chip carrier 110, it is advantageous that the chip carrier 110 is made of aluminium or has at least aluminium material on the surface 112 on which the adhesion enhancing structures 106 are grown hydrothermally. The material on the surface of the chip carrier 110 can then be modified or converted into the adhesion enhancing structures 106 thereon during the hydrothermal process.

Yet another detail 184 in FIG. 8 snows the (for instance clip-type or bond wire type) connection element 114 electrically connecting the chip carrier 110 with the pad 104 of the electronic chip 102. As shown, the package 100 comprises further hydrothermally formed adhesion enhancing structures 106 comprising aluminium, at an interface between the connection element 114 and the dielectric structure 108. In order to form, the adhesion enhancing structures 106 in a corresponding manner as described, above on the connection element 114, it is advantageous that the connection element 114 is made of aluminium or has at least aluminium material on the surface 112 on which the adhesion enhancing structures 106 are grown hydrothermally. The material on the surface of the connection element 114 can then be modified or converted into the adhesion enhancing structures 106 during the hydrothermal process. Thus, the connection element 114 electrically coupling the electronic chip 102 with the chip carrier 110 also has a surface 112 covered by the dielectric structure 108 and being provided with hydrothermally formed adhesion enhancing structures 106.

With embodiments, it may be possible to form, on a pad area for Al-based pads 104 and for Cu pads 104 covered, with ALD, adhesion enhancing structures 106. The homogenous dendrite layer leads to a homogenous optical appearance enabling a visual check of the process efficiency.

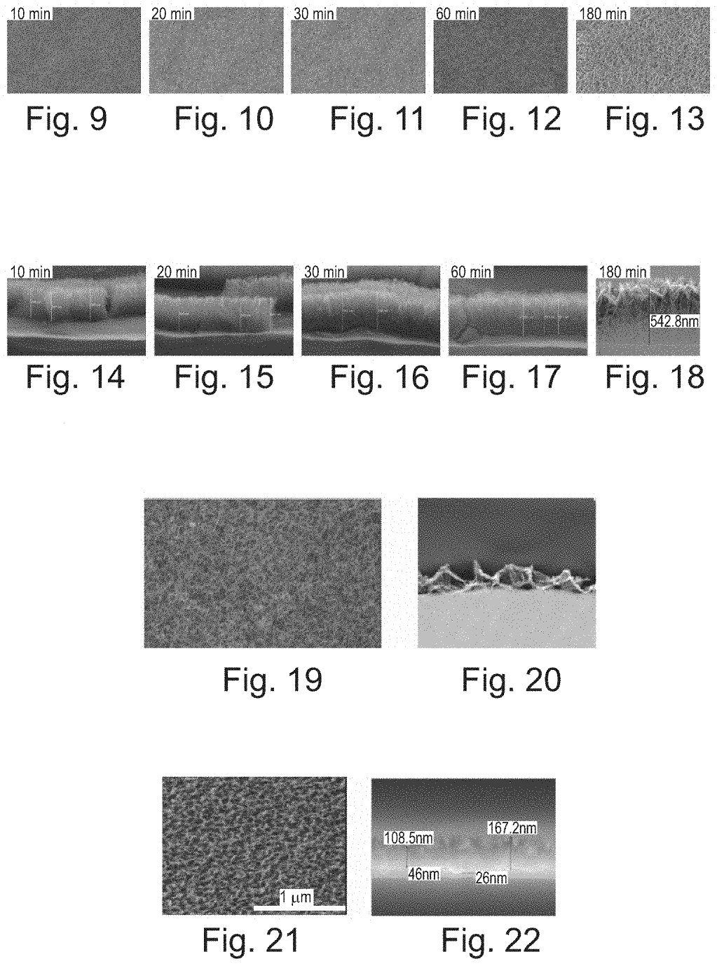

FIG. 9 to FIG. 13 show top views of the aluminium pad surface after exposure times of 10, 20, 30, 60 and 180 minutes, respectively. In other words, FIG. 9 to FIG. 13 show the surface morphology of aluminium, based, pads 104 after different durations. FIG. 14 to FIG. 18 show side views of this pad surface after exposure times of 10, 20, 30, 60 and 180 minutes, respectively. In the side views, the Al—O—H dendrites or adhesion enhancing structures 106 on aluminium based pads 104 are shown after different durations (images of 10-60 min taken of broken wafer with SEM, image of 180 min taken with TEM).

FIG. 19 shows a top view and FIG. 20 shows a side view of the surface after exposure of 20 min of an Al₂O₃ layer covered copper pad 104 using an ALD deposition process. The top- and side views of the Al—O—H dendrites on protected copper pads 104 after 20 minutes are shown (captured by TEM).

Both pads 104 show dendrite growth in the top view, while the thicknesses are varying with the exposure time, and the thickness for the ALD formed Al₂O₃ layer covered copper pad 104 is thinner. While the aluminium based pad 104 has about 600 nm thick dendrites, the latter case resulted in a 50 nm thick layer of adhesion promoting structures 106. In all cases the dendrite growth is very homogenous. The interface between the pad metal and the dendrites is very smooth without any signs of inhomogeneous corrosion and that the composition is as well.

Based on these analytical findings, it is possible to implement Al—H—O dendrites grown via temperature hydrolysis as adhesion promoter for robust packages. The analysis and evaluations have proven that it is possible to grow homogeneous dendrites as well on aluminium based metal areas as on ALD Al₂O₃ layer covered copper areas.

In view of this growth procedure, it is also possible to implement the hydrolysis on leadframe (or more general chip carrier 110) level. The copper areas of a package 100 may be covered by an ALD Al₂O₃ layer which can be deposited on the single package components (for instance copper pad 104, copper leadframe or other chip carrier 110) or after a wire bond process, for instance on the finished package 100.

FIG. 21 shows a top view of Al—O—H dendrites on ALD Al₂O₃ layer covered copper pads 104 after 10 minutes of spray-on of 70° C. hot deionized water. FIG. 22 shows a corresponding side view. FIG. 21 and FIG. 22 shows the result of an investigation where a wafer with an ALD-type Al₂O₃ layer protected copper pad 104 was exposed to humidity under high temperatures on a wet chemical etch tool. It shows that out of a 6 nm thin layer, thick dendrites are grown.

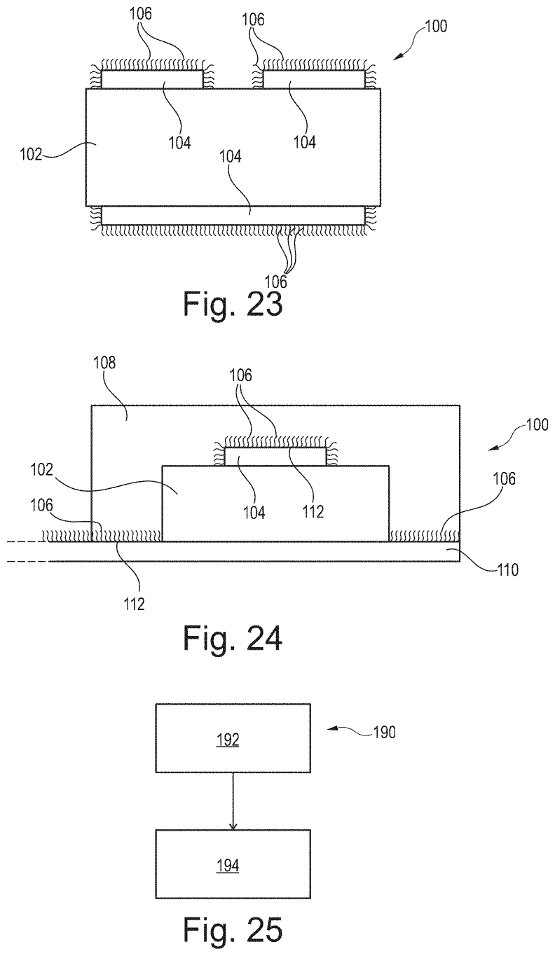

FIG. 23 illustrates a cross-sectional view of a package 100 according to an exemplary embodiment.

The package 100 of FIG. 23 comprises an electronic chip 102 having pads 104 covered with adhesion enhancing structures 106. The pads 104 and the adhesion enhancing structures 106 have a chemical element, for instance aluminium, in common.

FIG. 24 illustrates a cross-sectional view of a package 100 according to another exemplary embodiment.

The package 100 of FIG. 24 comprises a chip carrier 110, an electronic chip 102 mounted on the chip carrier 110, and a dielectric structure 108 covering a surface 112 of the chip carrier 110 and the electronic chip 102. The covered surface 112 comprises hydrothermally formed adhesion enhancing structures 106.

FIG. 25 is a flowchart 190 illustrating a method of forming a semiconductor package 100 according to an exemplary embodiment.

The method comprises providing an aluminium based surface 112 (see box 192), and roughening the surface 112 by forming adhesion enhancing structures 106 by a hydrothermal process (see box 194).

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

Although specific embodiments have been illustrated and. described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A package comprising an electronic chip having a pad, wherein the pad is at least partially covered with adhesion enhancing structures, and wherein the pad and the adhesion enhancing structures have at least aluminium in common.

2. The package of claim 1, further comprising a dielectric structure at least partly covering the electronic chip.

3. The package of claim 2, wherein at least a part of the adhesion enhancing structures is covered directly by the dielectric structure, and/or wherein the dielectric structure comprises a mold compound which at least partially encapsulates the electronic chip.

4. The package of claim 1, wherein the adhesion enhancing structures comprise at least one of aluminium oxide and aluminium hydroxide.

5. The package of claim 1, wherein the pad comprises at least one of pure aluminium, aluminium-copper, aluminium-silicon-copper, and copper with an aluminium oxide coating.

6. The package of claim 1, wherein the adhesion enhancing structures form a substantially homogeneous layer.

7. The package of claim 1, wherein the adhesion enhancing structures have a height in a range between 50 nm and 1000 nm.

8. The package of claim 1, wherein the adhesion enhancing structures comprise at least one of nanofibers and microfibers.

9. A package, comprising:
a chip carrier;
an electronic chip mounted on the chip carrier; and
a dielectric structure covering at least part of a surface of at least one of the chip carrier and the electronic chip,
wherein at least part of the covered surface comprises hydrothermally formed adhesion enhancing structures.

10. The package of claim 9, wherein at least one of the adhesion enhancing structures and the surface comprises aluminium.

11. The package of claim 9, further comprising a connection element electrically coupling the electronic chip with the chip carrier and having a surface which is at least partially covered by the dielectric structure, wherein the covered surface of the connection element comprises hydrothermally formed adhesion enhancing structures.

12. A method of forming a semiconductor package, the method comprising:
providing an aluminium based surface; and
roughening the surface by forming adhesion enhancing structures by a hydrothermal process.

13. The method of claim 12, wherein the adhesion enhancing structures comprise aluminium.

14. The method of claim 12, the adhesion enhancing structures are formed on an electrically conductive surface.

15. The method of claim 12, further comprising converting material of the surface into at least part of the adhesion enhancing structures.

16. The method of claim 12, further comprising providing an electronic chip with a pad, wherein the pad forms at least part of the surface.

17. The method of claim 12, wherein forming the adhesion enhancing structures comprises placing the surface in a heated aqueous solution.

18. The method of claim 17, further comprising at least one of:
heating the aqueous solution to a temperature in a range between 50° C. and 90° C.;
providing at least one of purified water, deionized water or distilled water as the aqueous solution; and
maintaining the surface in the heated aqueous solution for a time interval between 1 minute and 10 hours.

19. The method of claim 12, further comprising at least partially encapsulating the surface with the adhesion enhancing structures by a dielectric structure.

20. The method of claim 12, wherein the hydrothermal process comprises hydrothermally converting material of the surface into the adhesion enhancing structures.
